(19) United States
(12) Patent Application Publication
(10) Pub. No.: US 2008/0048658 A1
(43) Pub. Date: Feb. 28, 2008

(54) AUTOMATIC NOISE CANCELLATION FOR UNSHIELDED MR SYSTEMS

(76) Inventors: Stephen Gerard Hushek, Wauwatosa, WI (US); John Saunders, Winnipeg (CA); James Schellenberg, Winnipeg (CA)

Correspondence Address: ADE & COMPANY INC., 2157 Henderson Highway, WINNIPEG, MB, R2G1P9, US

(21) Appl. No.: 11/844,054

(22) Filed: Aug. 23, 2007

Related U.S. Application Data
(60) Provisional application No. 60/839,714, filed on Aug. 24, 2006.

(51) Int. Cl. G01R 33/56

(52) U.S. Cl. 324/309

(57) ABSTRACT

A signal processing system for active, environmental, electronic noise suppression is proposed. The system employs a noise sense coil outside the imaging volume to detect the environmental electronic noise, it subtracts the correlated noise in the environmental signal from the imaging signal. The noise suppression eliminates the need for the RF shield around the room containing the scanner.

This application claims the benefit under 35U.S.C.119 from Provisional Application 60/839714 filed Aug. 24^{th} 2006.

This invention relates to a method for effecting magnetic resonance imaging experiments which allows reduction in the deleterious effects of noise from other RF sources.

### BACKGROUND OF THE INVENTION

All MRI systems place the magnet inside an RF shield or Faraday cage to eliminate the corruption of the images by environmental RF noise and to reduce the amount of RF energy that is broadcast onto the public airwaves. The environmental RF noise can be from multiple sources including radio or TV stations, lightning or electronic emissions from other hospital electronic equipment. All electrical connections into the magnet room must go through filtered connectors so that noise is not carried in on conductors that act as antennas outside the room. Waveguides that prevent transmission of frequencies in the range of interest into the room are used for pneumatic or fiber-optic connections.

The construction of an RF shielded room adds expense to the construction of any MR scanner facility. The RF shielding construction can be particularly onerous for situations where it is desirable to install the MR system into an existing facility. MR systems were originally installed “on grade”, primarily to accommodate their weight and eliminate vibration of the system, which can significantly degrade image quality. Over time the system design has improved to the point where today there are minimal constraints on the siting of the magnets. Further, it is now desirable to install the scanners in areas of the hospital that have significant environment constraints of their own, specifically operating rooms. This can make it exceedingly difficult to renovate the existing space to accommodate the scanner.

U.S. Pat. No. 4,893,082 (Letcher) issued Jan. 9^{th} 1990 discloses an MRI system in which noise is sampled in the absence of the signal to be monitored but it does not incorporate the real-time collection of noise in separate channels that our patent does. It seems to rely more on previously acquired noise data that is still acquired in the same channel as the image signal.

U.S. Pat. No. 6,844,732 (Carlini) issued Jan. 18^{th} 2005 discloses an MRI system in which sensors detect noise signals and use algorithm steps for reducing the noise signals by generating compensatory magnetic fields in the magnet.

### SUMMARY OF THE INVENTION

It is one object of the invention to provide a method for effecting magnetic resonance imaging experiments which allows reduction in the deleterious effects of noise from other RF sources.

According to one aspect of the invention there is provided a method for effecting magnetic resonance imaging experiments comprising:

operating a magnet for generating a magnetic field containing an imaging volume;

locating a sample in the imaging volume of the magnetic field;

applying an energizing signal to a transmit coil to excite magnetization within the sample;

receiving RF signals from the sample in an imaging coil;

and analyzing the RF signals received from the sample to generate an image relating to the sample;

providing a noise pickup coil external to the imaging volume;

during the analysis of the RF signals, subtracting a correlated noise signal in the pickup coil from the signals obtained by the imaging coil;

so as to reconstruct a reduced noise image.

Preferably a scale factor is applied on the noise signal.

Preferably the scale factor on the noise signal is frequency dependent.

Preferably a frequency dependent phase shift is applied on the noise signal.

In one embodiment there is provided a plurality of noise pickup coils and wherein an identical processing is applied for the multiple noise pickup coils with independent scale, frequency dependent scale and frequency dependent phase shift factors for each noise pickup coil.

Preferably a series of signal acquisitions are used to determine all scale and/or shift factors, frequency dependent or not.

In one embodiment, the subtraction is done in the time domain.

Alternatively the subtraction is done in the frequency domain after FFTs have been performed.

Preferably there is provided a series of pre-scan steps in which one step in pre-scan steps looks at any image signal received by the noise pickup coils and senses that it is larger in the imaging coil than in the noise pickup coil and subsequently excludes it from the noise signal.

In one embodiment the pickup receiver system has properties which are arranged to match the properties of the image signal receiver system.

Alternatively the pickup receiver system has at least one property that does not match the properties of the image signal receiver system and a signal processing unit is built into it to match the properties of any coil/receiver combination used for imaging.

Preferably all processing is done automatically.

Preferably a series of signal acquisitions are made that are to determine all scale and/or shift factors, frequency dependent or not.

Preferably the magnet is mounted in a room which does not use a passive RF shield (Faraday cage) for environmental electronic noise suppression.

Alternatively the method can be used to provide electronic noise suppression within a passively RF shielded room (Faraday cage).

The invention described herein eliminates the noise cancellation requirement for the passive RF shielding accomplished via the use of a Faraday cage and replaces it with an active RF noise cancellation system. The active noise cancellation system detects and records the environmental electronic noise at all relevant frequencies, scales it appropriately, then subtracts that noise from the signal prior to image reconstruction. This allows the image to be reconstructed without any environmental electronic noise, thus eliminating the need for the Faraday cage or passive RF shield.

The system comprises one or more sense coils with associated preamplifiers that sense the environmental noise. The signals from these sense coils are transmitted to a single channel or multiple channels in the MR receiver. The signal processing associated with the active noise cancellation includes a calibration step where the sensitivity of the noise cancellation coils is calculated relative to the sensitivity of the imaging coils and the gain of the noise signal is adjusted. Where multiple noise sense coils are employed, as may be necessary due to the shielding effect of various metallic structures in the room or area and the potential directionality of the noise signals, each noise signal is calibrated independently and the sum of the noise cancellation signals scaled appropriately.

### BRIEF DESCRIPTION OF THE DRAWINGS

One embodiment of the invention will now be described in conjunction with the accompanying drawing in which:

FIG. 1 is a schematic illustration of the system according to the present invention.

FIG. 2 is a schematic illustration of an alternative chart showing how the data can be processed if the corrections were applied in the frequency domain (after the FFT).

### DETAILED DESCRIPTION

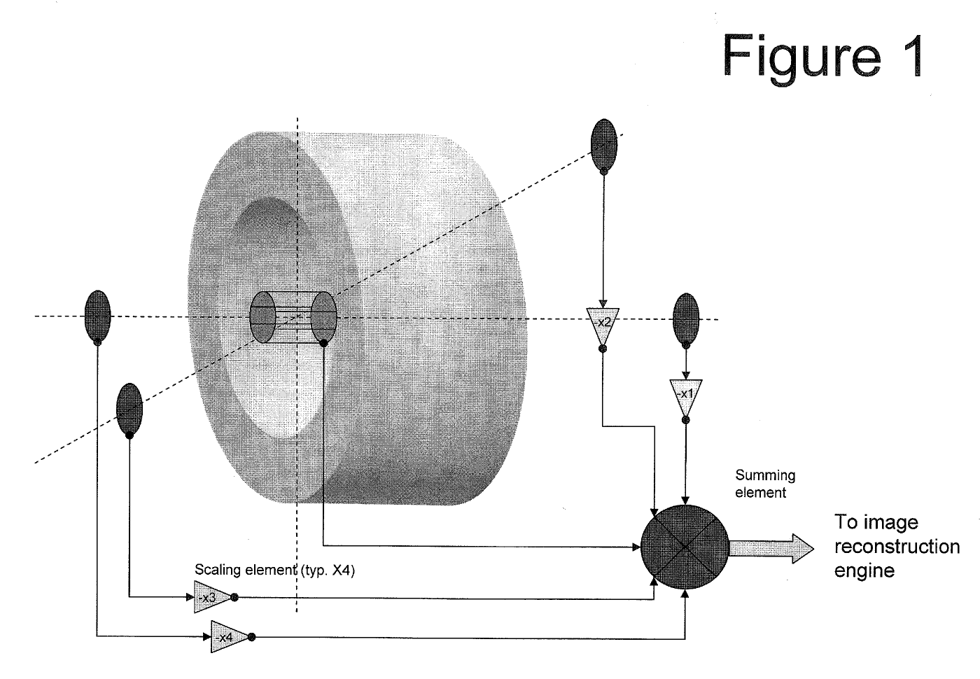

The concept is demonstrated schematically in FIG. 1. The scale factors from the noise pickup coils have a negative sign, thus signifying a subtraction.

Similarly, where the desired signal from the imaging volume is detected by the environmental noise sense coils, that signal is scaled down and eliminated from the noise signal. Otherwise the signal of interest would be considered noise and would be subtracted from the image, reducing the signal-to-noise ratio (SNR) of the image. An auto-correlation process which detects the relative size of the signals in the noise sense coils and the imaging coil can be used to automatically detect that the imaging signal is stronger in the imaging coil and thus should not be subtracted from the signal in the imaging coil.

The four sensors in FIG. 1 are only represented schematically. Experimentation or analysis can be carried out to indicate what the optimum position of the sense coils is. The sensors are preferably uniformly distributed and there is expected to be more than one sensor with the scale factors determined independently because of the directional nature of some of the noise.

FIG. 1 shows the data processing in the time domain, in that each sense coil is processed independently before all the data is combined.

The sense coils and their associated electronics can be designed in different ways, depending on the processing algorithms that are used to subtract the noise signal. If the sense coil receive electronics are designed to match the spectral sensitivity of the imaging coil receive electronics a simple scale function can be used to subtract the noise.

In some cases this is not sufficient because the attenuation of the environment may not be uniform across all frequencies, so a processing step is required to apply a frequency-dependent scale factor. A broadband receiver system with uniform sensitivity across as wide a bandwidth as possible is advantageous in this scenario.

The signal can be processed in the time domain or in the frequency domain. If signals are processed in the time domain, frequency dependent delays must be eliminated to maintain coherency in the signals. Equivalently, if signals are processed in the frequency domain, the phase of the signals must also be considered because MRI is a phase sensitive technique.

Thus during the analysis of the RF signals, the method acts to effect subtracting a correlated noise signal in the pickup coil from the signals obtained by the imaging coil so as to reconstruct a reduced noise image.

A scale factor is applied on the noise signal so that its magnitude is correlated to the required level to extract the noise without interfering with the actual signal to be sensed. The scale factor on the noise signal can be frequency dependent, that is the scale factor is different at different frequencies in the signals.

In another case a frequency dependent phase shift is applied on the noise signal. That is the noise signal is shifted in phase before being subtracted from the detected signals and the phase shift is varied at different frequencies in the signals.

There may be provided a plurality of noise pickup coils and an identical processing is applied for the multiple noise pickup coils with independent scale factor, frequency dependent scale factor and frequency dependent phase shift factors which can be applied to the signals for each noise pickup coil before the signals are subtracted from the detected signals.

In a calibration step prior to the processing of the signals, a series of signal acquisitions are used to determine all scale and/or shift factors, frequency dependent or not. Thus a series of signal acquisitions are made that can be used to determine all scale and/or shift factors, frequency dependent or not.

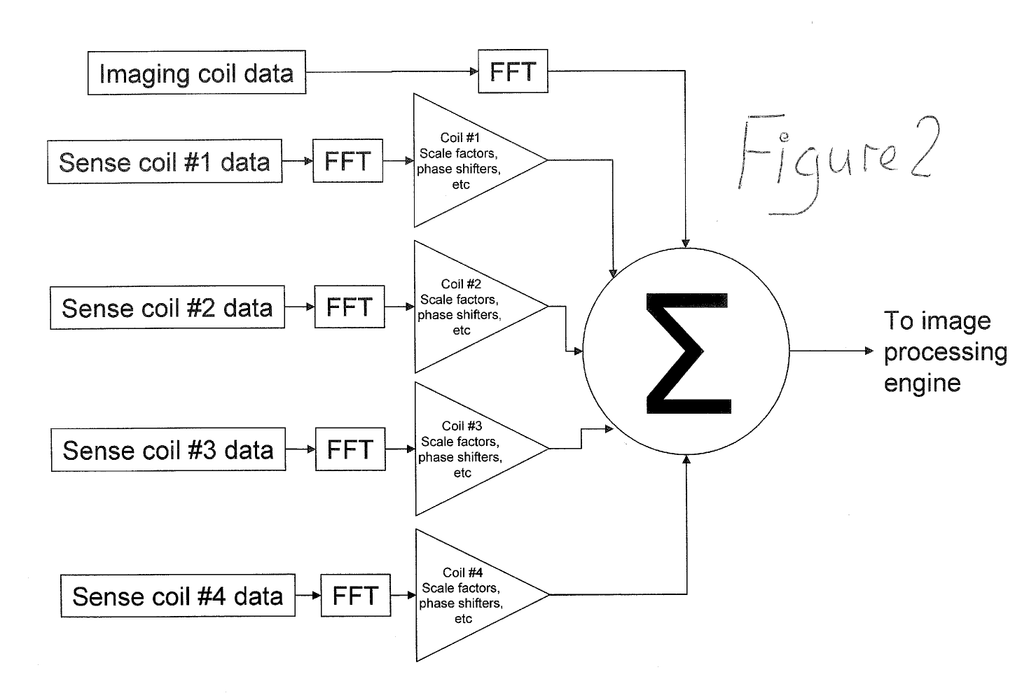

In one mode of processing the subtraction is done in the time domain. However in an alternative mode of processing, the subtraction is done in the frequency domain after FFTs have been performed. This is shown in FIG. 2.

As a further step in the initial or calibration process, there is provided a series of pre-scan steps in which one step in the pre-scan process steps looks at any image signal received by the noise pickup coils and senses that it is larger in the imaging coil than in the noise pickup coil and subsequently excludes it from the noise signal.

The pickup receiver system for the noise signals is selected such that it has properties which are arranged to match the properties of the image signal receiver system.

In the alternative the pickup receiver system has at least one property that does not match the properties of the image signal receiver system and, in this case, a signal processing unit is built into it to match the properties of any coil/receiver combination used for imaging.

All processing is done automatically as part of a processing system which controls the transmission signals and generates the images from the received signals.

The magnet can be mounted in a room which does not use a passive RF shield (Faraday cage) for environmental electronic noise suppression.

Alternatively, it provides electronic noise suppression if mounted within a passively RF shielded room (Faraday cage).

Since various modifications can be made in this invention as herein above described, and many apparently widely different embodiments of same made within the spirit and scope of the claims without department from such spirit and scope, it is intended that all matter contained in the accompanying specification shall be interpreted as illustrative only and not in a limiting sense.

1. A method for effecting magnetic resonance imaging experiments comprising:
operating a magnet for generating a magnetic field containing an imaging volume;
locating a sample in the imaging volume of the magnetic field;
applying an energizing signal to a transmit coil to excite magnetization within the sample;
receiving RF signals from the sample in an imaging coil;
and analyzing the RF signals received from the sample to generate an image relating to the sample;
providing a noise pickup coil external to the imaging volume;
during the analysis of the RF signals, subtracting a correlated noise signal in the pickup coil from the signals obtained by the imaging coil;
so as to reconstruct a reduced noise image.

2. The method according to claim 1 wherein a scale factor is applied on the noise signal.

3. The method according to claim 1 wherein the scale factor on the noise signal is frequency dependent.

4. The method according to claim 1 wherein a frequency dependent phase shift is applied on the noise signal.

5. The method according to claim 1 wherein there are provided a plurality of noise pickup coils and wherein an identical processing is applied for the multiple noise pickup coils with independent scale, frequency dependent scale and frequency dependent phase shift factors for each noise pickup coil.

6. The method according to claim 1 wherein a series of signal acquisitions are used to determine all scale and/or shift factors, frequency dependent or not.

7. The method according to claim 1 wherein the subtraction is done in the time domain.

8. The method according to claim 1 wherein the subtraction is done in the frequency domain after FFTs have been performed.

9. The method according to claim 1 wherein there is provided a series of pre-scan steps in which one step in the pre-scan process steps looks at any image signal received by the noise pickup coils and senses that it is larger in the imaging coil than in the noise pickup coil and subsequently excludes it from the noise signal.

10. The method according to claim 1 wherein the pickup receiver system has properties which are arranged to match the properties of the image signal receiver system.

11. The method according to claim 1 wherein the pickup receiver system has at least one property that does not match the properties of the image signal receiver system and a signal processing unit is built into it to match the properties of any coil/receiver combination used for imaging.

12. The method according to claim 1 wherein all processing is done automatically.

13. The method according to claim 1 wherein a series of signal acquisitions are made that can be used to determine all scale and/or shift factors, frequency dependent or not.

14. The method according to claim 1 wherein the magnet is mounted in a room which does not use a passive RF shield (Faraday cage) for environmental electronic noise suppression.

15. The method according to claim 1 which provides electronic noise suppression within a passively RF shielded room (Faraday cage).
